(19) United States
(12) Patent Application Publication
(10) Pub. No.: US 2021/0167121 A1
(43) Pub. Date: Jun. 3, 2021

(54) MICRO LED DISPLAY PANEL, AND PREPARATION METHOD THEREOF

(71) Applicants: Beijing BOE Display Technology Co., Ltd., Beijing (CN); BOE Technology Group Co., Ltd., Beijing (CN)

(72) Inventors: Yonglian QI, Beijing (CN); Hong Yang, Beijing (CN); Lianjie Qu, Beijing (CN); Shan Zhang, Beijing (CN); Hebin Zhao, Beijing (CN)

(73) Assignees: Beijing BOE Display Technology Co., Ltd.; BOE Technology Group Co., Ltd.

(21) Appl. No.: 16/830,987

(22) Filed: Mar. 26, 2020

(30) Foreign Application Priority Data
Nov. 29, 2019 (CN) 201911205281.3

(51) Int. Cl. H01L 27/15; H01L 33/62; H01L 33/44

(52) U.S. Cl. CPC H01L 27/156; H01L 33/62; H01L 2933/0066; H01L 2933/0025; H01L 33/44

(57) ABSTRACT

The present disclosure discloses a micro LED display panel and a preparation method thereof. The display panel includes a base substrate, including a first surface and a second surface opposite to each other; a plurality of micro LEDs and a driving circuit arranged on the base substrate; and a plurality of through structures and a plurality of metal film connecting portions.

This application claims priority to Chinese Patent Application No. 201911205281.3, filed on Nov. 29, 2019, which is hereby incorporated by reference in its entirety.

### FIELD

The present disclosure relates to the field of display devices, and in particular relates to a micro LED display panel, and a preparation method thereof.

### BACKGROUND

A micro LED display panel includes a miniaturized and matriculated micro LED array, having the characteristics of super high number of pixels, ultra high definition, low energy consumption and long service life. Compared with an organic light emitting diode (OLED) display panel, the micro LED display panel can reduce the distance between pixels from a millimeter level to a micron level, with a high color gamut.

### SUMMARY

The present disclosure provides a micro LED display panel and a preparation method thereof. The above micro LED display panel can realize accurate aligned connection of a signal line of a first surface with a signal lead of a second surface and avoid a metal film connecting portion generating a broken metal line.

The present disclosure provides a micro LED display panel, includes: a base substrate, including a first surface and a second surface opposite to each other; a plurality of micro LEDs and a driving circuit arranged on the base substrate, where the plurality of micro LEDs are arranged on the first surface of the base substrate, the driving circuit includes a plurality of signal lines arranged on the first surface of the base substrate and a plurality of signal leads arranged on the second surface of the base substrate and in one-to-one correspondence to respective signal lines of the plurality of signal lines, and a first end of each signal line of the plurality of signal lines and a second end of each signal lead of the plurality of signal leads extend to a preset edge area of the base substrate; and a plurality of through structures and a plurality of metal film connecting portions arranged at the preset edge area and in one-to-one correspondence to the respective signal lines, where each through structure of the plurality of through structures connects the first surface and the second surface, each metal film connecting portion of the plurality of metal film connecting portions at least includes a first metal film connecting portion plated on a side wall of a corresponding through structure, and two ends of the each metal film connecting portion are respectively connected to a corresponding signal line and a corresponding signal lead.

Optionally, the each metal film connecting portion further includes a second metal film connecting portion and a third metal film connecting portion, where the second metal film connecting portion is plated around the corresponding through structure on the first surface, the third metal film connecting portion is plated around the corresponding through structure on the second surface, the second metal film connecting portion is connected to the first metal film connecting portion and the corresponding signal line, and the third metal film connecting portion is connected to the first metal film connecting portion and the corresponding signal lead.

Optionally, the each through structure includes a concave part on a plane connecting the first surface and the second surface.

Optionally, the plurality of through structures are micro through holes arranged at the preset edge area of the base substrate.

Optionally, cross-sectional shape of the plurality of through structures parallel to the first surface is a circle or an arc, a diameter of the circle ranges from 10 μm to 50 μm, and a diameter of a circle where the arc is located ranges from 50 μm to 100 μm.

Optionally, a thickness of the each metal film connecting portion ranges from 0.5 μm to 1.5 μm.

Optionally, a material of the each metal film connecting portion includes any one of copper, aluminum or silver.

The present disclosure further provides a method for preparing a micro LED display panel, including: forming a plurality of micro LEDs and a driving circuit on a base substrate, where the base substrate includes a first surface and a second surface opposite to each other, the plurality of micro LEDs are formed on the first surface of the base substrate, the driving circuit includes a plurality of signal lines formed on the first surface of the base substrate and a plurality of signal leads formed on the second surface of the base substrate and in one-to-one correspondence to respective signal lines of the plurality of signal lines, and a first end of each signal line of the plurality of signal lines and a second end of each signal lead of the plurality of signal leads extend to a preset edge area of the base substrate; covering a protection film on the first surface and the second surface of the base substrate, where the protection film covers an area outside the preset edge area; and forming a plurality of through structures and a plurality of metal film connecting portions at the preset edge area and in one-to-one correspondence to the respective signal lines, where each through structure of the plurality of through structures connects the first surface and the second surface, each metal film connecting portion of the plurality of metal film connecting portions at least includes a first metal film connecting portion plated on a side wall of a corresponding through structure, and two ends of the each metal film connecting portion are respectively connected to a corresponding signal line and a corresponding signal lead.

Optionally, the each metal film connecting portion further includes a second metal film connecting portion and a third metal film connecting portion, where the second metal film connecting portion is plated around the corresponding through structure on the first surface, the third metal film connecting portion is plated around the corresponding through structure on the second surface, the second metal film connecting portion is connected to the first metal film connecting portion and the corresponding signal line, and the third metal film connecting portion is connected to the first metal film connecting portion and the corresponding signal lead.

Optionally, the forming the plurality of through structures and the plurality of metal film connecting portions at the preset edge area and in one-to-one correspondence to the respective signal lines, includes: forming a plurality of through holes at the preset edge area and in one-to-one correspondence to the respective signal lines, where centers of the plurality of through holes are located on a same cutting line; at least plating metal films on side walls of respective through holes of the plurality of through holes; cutting the base substrate along the cutting line, and forming the plurality of through structures on a cutting surface connecting the first surface and the second surface, where the plurality of through structures include concave parts that are parts of the side walls of the respective through holes; and forming the plurality of metal film connecting portions.

Optionally, the forming the plurality of through structures and the plurality of metal film connecting portions at the preset edge area and in one-to-one correspondence to the respective signal lines, includes: forming a plurality of through holes at the preset edge area and in one-to-one correspondence to the respective signal lines, where centers of the plurality of through holes are located on a same cutting line; cutting the base substrate along the cutting line, and forming the plurality of through structures on a cutting surface connecting the first surface and the second surface, where the plurality of through structures include concave parts that are parts of the side walls of the respective through holes; at least plating metal films on the cutting surface on which the plurality of through structures are located; and grinding to remove the metal films arranged at an area outside the plurality of through structures, and forming the plurality of metal film connecting portions.

Optionally, the forming the plurality of through structures and the plurality of metal film connecting portions at the preset edge area and in one-to-one correspondence to the respective signal lines, includes: forming a plurality of micro through holes at the preset edge area and in one-to-one correspondence to the respective signal lines; at least plating metal films on a side wall of the plurality of micro through holes, and forming the plurality of metal film connecting portions; and tearing off the protection film.

Optionally, cross-sectional shape of the plurality of through structures parallel to the first surface is a circle or an arc, a diameter of the circle ranges from 10 μm to 50 μm, and a diameter of a circle where the arc is located ranges from 50 μm to 100 μm.

Optionally, a method of forming the plurality of through holes includes any one of a laser method, a sandblasting method or an etching method.

Optionally, a method of plating the metal films includes any one of a magnetron sputtering method, a three-dimensional evaporation method, a micro plating method or an electroless plating method.

### BRIEF DESCRIPTION OF THE DRAWINGS

FIG. 1 is a structural diagram of a micro LED display panel provided by an embodiment of the present disclosure.

FIG. 2 is a structural diagram of a micro LED display panel provided by an embodiment of the present disclosure.

FIG. 3 is a structural diagram of a micro LED display panel provided by an embodiment of the present disclosure.

FIG. 4 is a flow chart of preparing a micro LED display panel provided by an embodiment of the present disclosure.

FIGS. 5-6 are a schematic diagram of a process of preparing a micro LED display panel provided by an embodiment of the present disclosure.

FIG. 7 is a flow chart of preparing through structures and metal film connecting portions provided by an embodiment of the present disclosure.

FIGS. 8A, 8B, 8C and 8D are a schematic diagram of a process of preparing a micro LED display panel provided by an embodiment of the present disclosure.

FIG. 9 is a flow chart of preparing through structures and metal film connecting portions provided by an embodiment of the present disclosure.

FIGS. 10A, 10B, 10C and 10D are a schematic diagram of a process of preparing a micro LED display panel provided by an embodiment of the present disclosure.

FIG. 11 is a flow chart of preparing through structures and metal film connecting portions provided by an embodiment of the present disclosure.

FIG. 12 is a schematic diagram of a process of preparing a micro LED display panel provided by an embodiment of the present disclosure.

Reference markers: 1—base substrate; 2—micro LED; 3—signal line; 4—protection film; 5: 51—through hole; 52—micro through hole; 6—metal film; 7—through structure; 8—a metal film connecting portion; 81—a first metal film connecting portion; 82—a second metal film connecting portion.

### DETAILED DESCRIPTION OF THE EMBODIMENTS

Accompanying drawings in embodiments of the present disclosure will be incorporated below to describe the technical solution in the embodiments of the present disclosure clearly and completely. Obviously, the embodiments described are merely a part of embodiments of the present disclosure rather than all embodiments. Based on the embodiments of the present disclosure, all other embodiments obtained by those skilled in the art under the precondition of not paying creative labor should belong to the protection scope of the present disclosure.

In the related art, the micro LED display panel realizes super-large-size display through splicing. At present, the structure of the micro LED display, due to size restriction of transfer of micro LEDs in a huge amount on a substrate, needs to perform high-precision cutting of a laser after an overall front and back process is manufactured on the substrate, so as to ensure thermal injury as small as possible after cutting, without causing any damage around pixels. Moreover, only with a small process allowance, seamless splicing can be realized. Meanwhile, in order to realize seamless splicing, it is required to coat and pattern metal on a side edge of a small-sized substrate and connect a front pixel to a back metal line. Afterward, a black protection layer is coated on a metal line formed through patterning for placing metal oxidation and metal reflection. At present, a distance between metal lines is around 50 μm to 200 μm. Moreover, strict and accurate alignment is required so as to ensure that the metal line makes a front pixel accurately connected to a back line. In addition, it is required to ensure a metal line at a connecting point of front and back faces with a side edge (i.e. at an edge formed by the side edge with front and back faces) not broken. At present, in performing the process, after cutting into small sizes by the laser, it is required to wear off an angle (45° to 60°) firstly at vertical edges. By doing this, the metal line of the side edge can be made to realize connection of front and back circuits; otherwise, mobile print cannot perform printing and alignment of the metal line at a right angle.

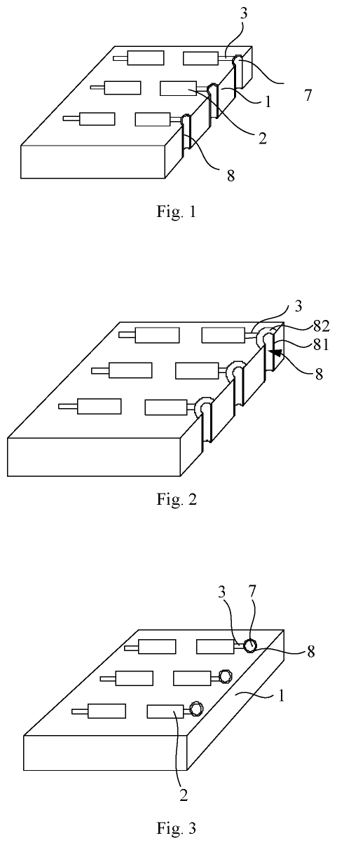

An embodiment of the present disclosure provides a micro LED display panel, as shown in FIG. 1.

The macro LED display panel includes a base substrate 1, including a first surface and a second surface opposite to each other; a plurality of micro LEDs 2 and a driving circuit arranged on the base substrate 1, where the micro LEDs 2 are arranged on the first surface of the base substrate 1, the driving circuit includes a plurality of signal lines 3 arranged on the first surface of the base substrate 1 and a plurality of signal leads arranged on the second surface of the base substrate 1 and in one-to-one correspondence to respective signal lines, and a first end of each of the signal lines 3 and a second end of each of the signal leads extend to a preset edge area of the base substrate 1; and a plurality of through structures 7 and a plurality of metal film connecting portions 8 arranged at the preset edge area and in one-to-one correspondence to the respective signal lines 3, where each through structure 7 connects the first surface and the second surface, each metal film connecting portion 8 at least includes a first metal film connecting portion plated on a side wall of a corresponding through structure, and two ends of the each metal film connecting portion 8 are respectively connected to a corresponding signal line 3 and a corresponding signal lead.

The above micro LED display panel, by forming the plurality of through structures 7 at the preset edge area of the base substrate 1 and in one-to-one correspondence to the signal lines 3 and at least forming the metal film connecting portions 8 in the plurality of through structures 7, can realize accurate aligned connection of the signal lines 3 of the first surface with the signal leads of the second surface. Since the metal film connecting portions 8 are plated to the side walls of the plurality of through structures 7, a forming process is made through multi-layer deposition of atoms. Compared with a solution of mobile print in the related art, it can avoid the problem of generating a broken metal line by connecting portions, such that a solution of seamless splicing is provided for realizing large-size display through highly accurate splicing at a side edge, realizing advantages of high accuracy, small splicing crack and easy mass production.

In some embodiments, as shown in FIG. 2, each metal film connecting portion 8 includes a first metal film connecting portion 81, a second metal film connecting portion 82 and a third metal film connecting portion. The first metal film connecting portions 81 are plated on the side walls of the plurality of through structures, the second metal film connecting portions 82 are plated around the plurality of through structures on the first surface, and the third metal film connecting portions plated around the plurality of through structures on the second surface. The second metal film connecting portions 82 are connected to the first metal film connecting portions 81 and corresponding signal lines 3. The third metal film connecting portions are connected to the first metal film connecting portions and corresponding signal leads.

Optionally, the cross-sectional shape of the plurality of through structures parallel to the first surface is a shape such as a circle, an arc, a square, an ellipse, or other shapes, which are not limited herein.

In some embodiments, as shown in FIG. 1, each through structure 7 includes a concave part on a plane connecting the first surface and the second surface. For example, the cross-sectional shape of a through structure including a concave part, parallel to the first surface is an arc, where a diameter of a circle where the arc is located ranges from 50 μm to 100 μm, or may be other ranges, which may be determined according to an actual situation.

Optionally, as shown in FIG. 3, the through structures 7 can also be micro through holes arranged at the preset edge area of the base substrate 1. For example, the cross-sectional shape of a micro through hole that is parallel to the first surface may be a circle, where a diameter of the circle ranges from 10 μm to 50 μm.

In some embodiments, a thickness of the above metal film connecting portion ranges from 0.5 μm to 1.5 μm. For example, a thickness of the metal film connecting portion may be 0.5 μm, 1 micron, or 1.5 μm.

In some embodiments, a material of the above metal film connecting portions can be copper, aluminum or silver and the like and can also be other conductive metals, which are not defined herein, as it should be determined according to an actual situation.

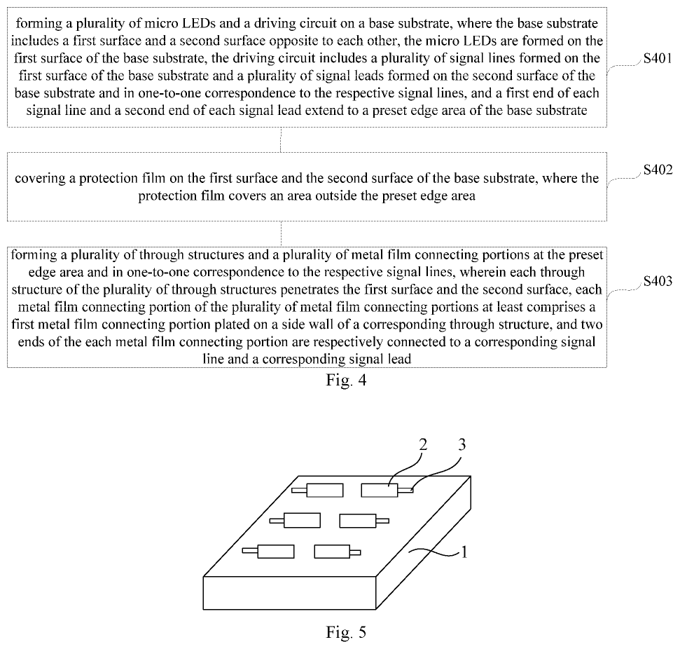

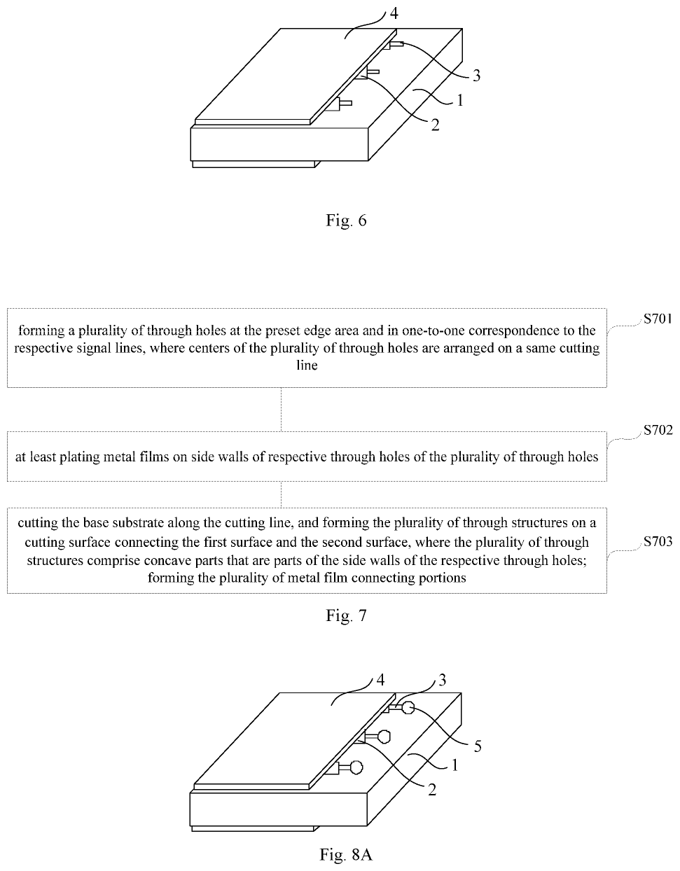

Based on the same inventive concept, as shown in FIG. 4, FIG. 5 and FIG. 6, the present disclosure further provides a method for preparing a micro LED display panel. The method includes steps S401 to S403 as shown in FIG. 4.

Step S401: forming a plurality of micro LEDs and a driving circuit on a base station, where the base substrate includes a first surface and a second surface opposite to each other, the micro LEDs are formed on the first surface of the base substrate, the driving circuit includes a plurality of signal lines formed on the first surface of the base substrate and a plurality of signal leads formed on the second surface of the base substrate and in one-to-one correspondence to the respective signal lines, and a first end of each signal line and a second end of each signal lead extend to a preset edge area of the base substrate.

In some embodiments, with a structure formed in the step S401 shown in FIG. 5, the plurality of micro LEDs 2 and the driving circuit are provided on the base substrate 1, the driving circuit includes the plurality of signal lines 3 formed on a first surface of the base substrate 1 and the plurality of signal leads formed on a second surface of the base substrate and in one-to-one correspondence to the signal lines 3.

Step S402: covering a protection film on the first surface and the second surface of the base substrate, where the protection film covers an area outside the preset edge area.

In some embodiments, with a structure formed in the step S402 shown in FIG. 6, protection films 4 cover the first surface and the second surface of the base substrate 1, and the protection films 4 protect areas which do not need to be plated with metal films.

Step S403: forming a plurality of through structures and a plurality of metal film connecting portions at the preset edge area and in one-to-one correspondence to the respective signal lines, where each through structure of the plurality of through structures connects the first surface and the second surface, each metal film connecting portion of the plurality of metal film connecting portions at least includes a first metal film connecting portion plated on a side wall of a corresponding through structure, and two ends of the each metal film connecting portion are respectively connected to a corresponding signal line and a corresponding signal lead.

In the above method for preparing a micro LED display panel provided by the embodiment of the present disclosure, firstly a plurality of micro LEDs and a driving circuit for driving the micro LEDs to light are formed on a base substrate. The driving circuit includes a plurality of signal lines formed on a first surface of the base substrate and a plurality of signal leads formed on a second surface of the base substrate and in one-to-one correspondence to the signal lines, and a first end of each signal line of the plurality of signal lines and a second end of each signal lead of the plurality of signal leads extend to a preset edge area of the base substrate.

Then protection films cover the first surface and the second surface of the base substrate at an area outside the preset edge area for protecting areas which do not need to be plated with metal films, and exposing areas needing to be plated with metal.

Finally, the plurality of through structures and metal film connecting portions are formed at the preset edge area and in one-to-one correspondence to the signal lines, where each through structure of the plurality of through structures connects the first surface and the second surface, and the metal film connecting portions at least including first metal film connecting portions plated on side walls of the plurality of through structures, to make the corresponding signal lines electrically connected to the signal leads.

The above preparing method, by forming the plurality of through structures at the preset edge area and in one-to-one correspondence to the signal lines and at least forming the metal film connecting portions in the plurality of through structures, can realize accurate aligned connection of the signal lines of the first surfaces with the signal leads of the second surface.

Since the metal film connecting portions are plated on the side walls of the plurality of through structures, a forming process is made through multi-layer deposition of atoms. Compared with a solution of mobile print in the related art, it can avoid the problem of generating a broken metal line by connecting portions, such that a solution of seamless splicing is provided for realizing large-size display through highly accurate splicing at a side edge, resulting in advantages of high accuracy, small splicing crack and easy mass production.

In the above method for preparing the micro LED display panel, each metal film connecting portion further includes a second metal film connecting portion and a third metal film connecting portion, where the second metal film connecting portion is plated around the corresponding through structure on the first surface, the third metal film connecting portion is plated around the corresponding through structure on the second surface, the second metal film connecting portion is connected to the first metal film connecting portion and the corresponding signal line, and the third metal film connecting portion is connected to the first metal film connecting portion and the corresponding signal lead. The metal film connecting portions can realize accurate aligned connection of respective signal lines of the first surface to respective signal leads of the second surface and avoid the problem of generating a broken metal line by a connecting portion.

Optionally, the cross-sectional shape of the plurality of through structures parallel to the first surface is a shape such as a circle, an arc, a square, an ellipse, or other shapes, which are not limited herein.

In the above method for preparing the micro LED display panel, in some embodiments, the method of forming the plurality of through structures and the plurality of metal film connecting portions at the preset edge area and in one-to-one correspondence to signal lines, may have the following three embodiments.

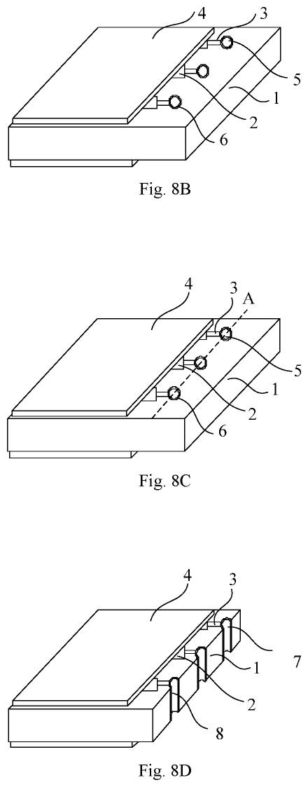

In a specific embodiment, as shown in FIG. 7, and FIGS. 8A-8D, steps of forming the plurality of through structures and the plurality of metal film connecting portions at the preset edge area and in one-to-one correspondence to the signal lines may include S701-S703 as shown in FIG. 7.

Step S701: forming a plurality of through holes at the preset edge area and in one-to-one correspondence to the respective signal lines, where centers of the plurality of through holes are arranged on a same cutting line.

In some embodiments, as shown in FIG. 8A, through holes 5 in one-to-one correspondence to signal lines 3 are provided at a preset edge area of the base substrate 1 in a structure formed in the step S701.

Step S702: at least plating metal films on side walls of respective through holes of the plurality of through holes.

As shown in FIG. 8B, metal films 6 are provided on side walls of the through holes 5.

Step S703: cutting the base substrate along the cutting line, and forming the plurality of through structures on a cutting surface connecting the first surface and the second surface, where the plurality of through structures include concave parts that are parts of the side walls of the respective through holes; forming the plurality of metal film connecting portions.

As shown in FIG. 8C, the substrate is cut along a cutting line A, thereby forming the plurality of through structures 7 and the plurality of metal film connecting portions 8 as shown in FIG. 8D.

In the specific embodiment, firstly a plurality of through holes in one-to-one correspondence to signal lines are formed at a preset edge area of a base station; then, at least metal films are plated on side walls of the through holes; and finally, the base substrate is cut along a cutting line, thereby forming the plurality of through structures on a cutting surface connecting the first surface and the second surface and at least metal film connecting portions arranged on side walls of the plurality of through structures. The specific embodiment can realize accurate aligned connection of the signal lines of a first surface with signal leads of a second surface and avoid the problem of generating a broken metal line by connecting portions.

In some embodiments, in the above specific embodiment, metal films can also be plated on the side walls of the through holes and around the through holes in step S702; and after cutting the base substrate in step S703, the metal film connecting portions formed includes first metal film connecting portions, second metal film connecting portions and third metal film connecting portions.

In some embodiments, tearing off the protection films is further included before step S703; or tearing off the protection films is included after step S703, such that a part shielded by the protection films is exposed and metal deposited on the protection films also falls off, as shown in FIG. 1.

It should be noted that shapes of the above through holes can be square, circular, arc or oval and the like, and can also be other shapes, which are not defined herein.

In some embodiments, when the through holes formed in step S701 are circular holes, a diameter of the holes ranges from 50 μm to 100 μm.

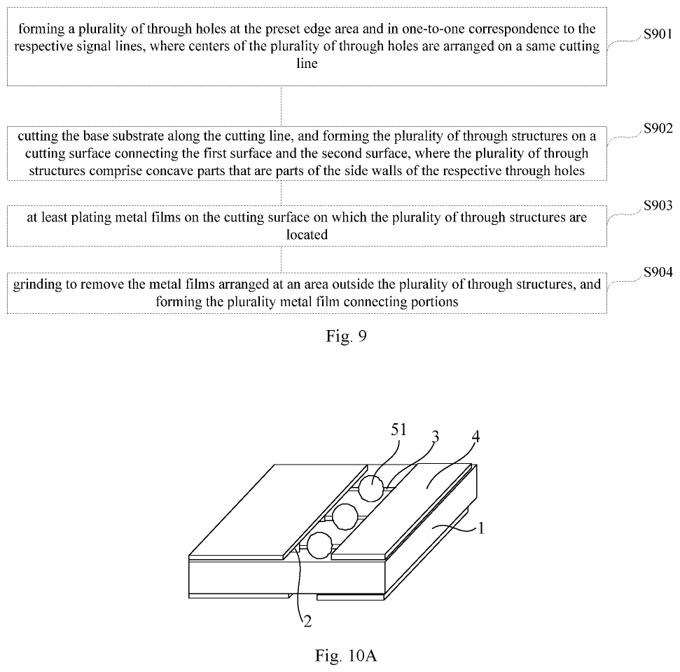

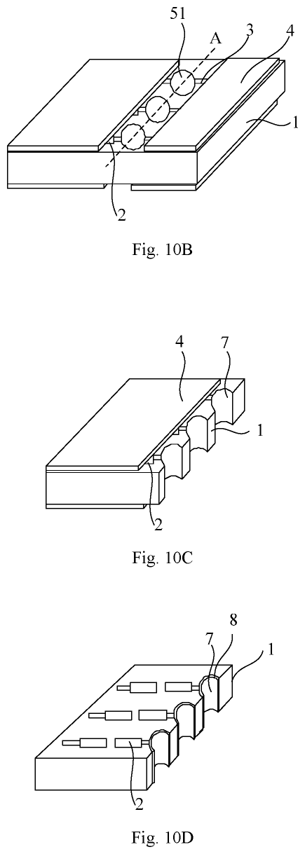

In another specific embodiment, as shown in FIG. 9, and FIGS. 10A-10D, steps of forming the plurality of through structures and the plurality of metal film connecting portions at a preset edge area and in one-to-one correspondence to the respective signal lines includes S901-S904.

Step S901: forming a plurality of through holes at the preset edge area and in one-to-one correspondence to the respective signal lines, where centers of the plurality of through holes are arranged on a same cutting line.

As shown in FIG. 10A, through holes 51 in one-to-one correspondence to signal lines 3 are provided at a preset edge area of a base station 1 in a structure formed in the step.

Step S902: cutting the base substrate along the cutting line, and forming the plurality of through structures on a cutting surface connecting the first surface and the second surface, where the plurality of through structures include concave parts that are parts of the side walls of the respective through holes.

As shown in FIG. 10B, the base substrate 1 is cut along a cutting line B, thereby forming the plurality of through structures 7 as shown in FIG. 10C.

Step S903: at least plating metal films on the cutting surface on which the plurality of through structures are located.

Step S904: grinding to remove the metal films arranged at an area outside the plurality of through structures, and forming the plurality metal film connecting portions.

As shown in FIG. 10D, metal film connecting portions 8 are formed.

In the specific embodiment, firstly a plurality of through holes in one-to-one correspondence to signal lines are formed at a preset edge area of a base station, centers of the plurality of through holes being arranged on a same cutting line; then, the base substrate is cut along the cutting line, thereby forming plurality of through structures on a cutting surface connecting the first surface and the second surface; next, at least metal films are plated on the cutting surface of the base substrate having the plurality of through structures; and finally metal films on the base substrate and arranged at an area outside the plurality of through structures is ground to be removed, to make metal of the entire cutting surface broken at an edge of the ground plurality of through structures and form metal film connecting portions. The specific embodiment can realize accurate aligned connection of the signal lines of a first surface with signal leads of a second surface and avoid the problem of generating a broken metal line by connecting portions. What is more, adopting a solution of performing perforating and cutting first and plating copper second can avoid the problem of large heat-affected area caused by cutting after the metal films are plated.

In the above specific embodiments, in step S902, metal films can also be plated on side walls of respective concave parts and around the respective concave parts.

In some embodiments, tearing off the protection films is further included before step S904, such that a part shielded by the protection films is exposed and metal deposited on the protection films also falls off.

It should be noted that shapes of the above through holes can be square, circular or oval and the like, and can also be other shapes, which are not defined herein.

In the above specific embodiments, when the through holes formed in step S901 are circular holes, a diameter of the holes ranges from 50 μm to 100 μm.

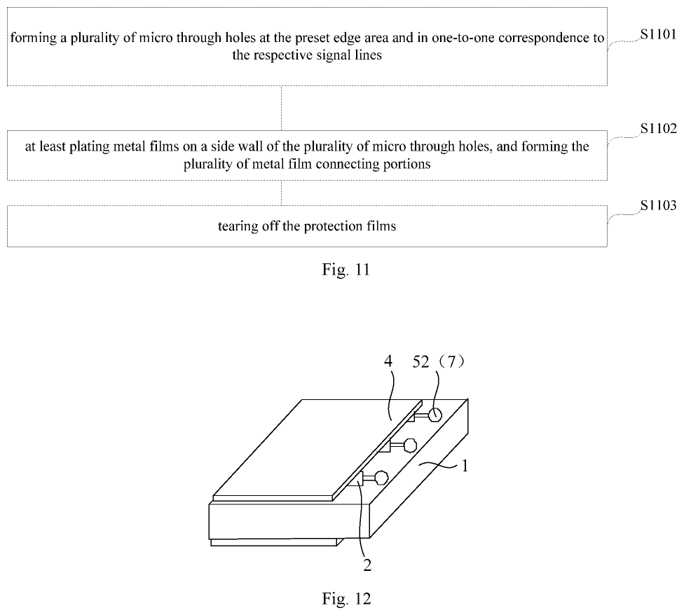

In another specific embodiment, as shown in FIG. 11, FIG. 12 and FIG. 3, steps of forming the plurality of through structures and connecting portions at a preset edge area and in one-to-one correspondence to the signal lines may also include S1101-S1103 as shown in FIG. 11.

Step S1101: forming a plurality of micro through holes at the preset edge area and in one-to-one correspondence to the respective signal lines.

As shown in FIG. 12, micro through holes 52 are provided at a preset edge area of a base substrate 1, and the plurality of through structures 7 are formed.

Step S1102: at least plating metal films on a side wall of the plurality of micro through holes, and forming the plurality of metal film connecting portions.

Step S1103: tearing off the protection films.

As shown in FIG. 3, metal film connecting portions 8 are provided on side walls of the plurality of through structures 7.

The specific embodiment adopts micro through holes, without cutting. With only perforating and copper plating techniques, accurate aligned connection of signal lines of a first surface with signal leads of a second surface can be realized.

It should be noted that shapes of the above micro through holes can be square, circular or oval vacancy and the like, and can also be other shapes, which are not defined herein.

In the embodiments, the cross-sectional shape of a micro through hole that is parallel to the first surface may be a circle, where a diameter of the circle ranges from 10 μm to 50 μm.

In the above three specific embodiments, according to the diameter of the through structures and a size of the distance between the through structures, display panels of different display levels and resolutions can be respectively corresponding to. In some embodiments, in the above specific embodiments, with a length of the metal film connecting portions being l, and a width (a perimeter of a concave part) of the metal film connecting portions being w, the width of the metal film connecting portions can be obtained through calculation according to the following formula:

R=Rs*(l/w),

Where R denotes resistance required by the metal film connecting portions; and Rs sheet resistance of the metal.

After obtaining the width of the metal film connecting portions through calculation, upon forming through holes, a diameter d of the through holes can be obtained through calculation according to the following formula: w=0.5*πd.

In some embodiments, in the preparing method provided by the embodiment of the present disclosure, a thickness of the metal films ranges from 0.5 μm to 1.5 μm. For example, a thickness of the metal films may be 0.5 μm, 1 μm or 1.5 μm.

In some embodiments, in the preparing method provided by the embodiment of the present disclosure, a material of the metal films can be copper, aluminum or silver and the like and can also be other conductive metals, which are not defined herein, as it should be determined according to an actual situation.

In some embodiments, in the preparing method provided by the embodiment of the present disclosure, the through holes on the base substrate can be formed through a laser method, a sandblasting method or an etching method and the like.

In some embodiments, in the preparing method provided by the embodiment of the present disclosure, a method of plating the metal films can be a magnetron sputtering method, a three-dimensional evaporation method, a micro plating method or an electroless plating etc.

It should be noted that in the preparing method of the micro Light Emitting Diode (LED) display panel provided by the embodiment of the present disclosure, the preset edge area of the base substrate can be one and can also be multiple. All ends of the signal lines on the micro LED display panel can extend to one preset edge area and can also extend respectively to different preset edge areas. If the signal lines extend to the different preset edge areas, it is required to cut the different preset edge areas upon cutting the base substrate.

Obviously, those skilled in the art can make various modifications and variations to embodiments of the present disclosure without departing from the spirit and scope of the present disclosure. By doing this, if these modifications and variations to the present disclosure belong to the claims of the present disclosure and equivalent techniques thereof, the present disclosure also intends to include these modifications and variations inside.

1. A micro light emitting diode (LED) display panel, comprising:
a base substrate, comprising a first surface and a second surface opposite to each other;
a plurality of micro LEDs and a driving circuit arranged on the base substrate, wherein the plurality of micro LEDs are arranged on the first surface of the base substrate, the driving circuit comprises a plurality of signal lines arranged on the first surface of the base substrate and a plurality of signal leads arranged on the second surface of the base substrate and in one-to-one correspondence to respective signal lines of the plurality of signal lines, and a first end of each signal line of the plurality of signal lines and a second end of each signal lead of the plurality of signal leads extend to a preset edge area of the base substrate; and
a plurality of through structures and a plurality of metal film connecting portions arranged at the preset edge area and in one-to-one correspondence to the respective signal lines, wherein each through structure of the plurality of through structures connects the first surface and the second surface, each metal film connecting portion of the plurality of metal film connecting portions at least comprises a first metal film connecting portion plated on a side wall of a corresponding through structure, and two ends of the each metal film connecting portion are respectively connected to a corresponding signal line and a corresponding signal lead.

2. The micro LED display panel according to claim 1, wherein the each metal film connecting portion further comprises a second metal film connecting portion and a third metal film connecting portion, wherein the second metal film connecting portion is plated around the corresponding through structure on the first surface, the third metal film connecting portion is plated around the corresponding through structure on the second surface, the second metal film connecting portion is connected to the first metal film connecting portion and the corresponding signal line, and the third metal film connecting portion is connected to the first metal film connecting portion and the corresponding signal lead.

3. The micro LED display panel according to claim 1, wherein the each through structure comprises a concave part on a plane connecting the first surface and the second surface.

4. The micro LED display panel according to claim 1, wherein the plurality of through structures are micro through holes arranged at the preset edge area of the base substrate.

5. The micro LED display panel according to claim 1, wherein cross-sectional shape of the plurality of through structures parallel to the first surface is a circle or an arc, a diameter of the circle ranges from 10 μm to 50 μm, and a diameter of a circle where the arc is located ranges from 50 μm to 100 μm.

6. The micro LED display panel according to claim 1, wherein a thickness of the each metal film connecting portion ranges from 0.5 μm to 1.5 μm.

7. The micro LED display panel according to claim 1, wherein a material of the each metal film connecting portion comprises any one of copper, aluminum or silver.

8. A method for preparing a micro light emitting diode (LED) display panel, comprising:
forming a plurality of micro LEDs and a driving circuit on a base substrate, wherein the base substrate comprises a first surface and a second surface opposite to each other, the plurality of micro LEDs are formed on the first surface of the base substrate, the driving circuit comprises a plurality of signal lines formed on the first surface of the base substrate and a plurality of signal leads formed on the second surface of the base substrate and in one-to-one correspondence to respective signal lines of the plurality of signal lines, and a first end of each signal line of the plurality of signal lines and a second end of each signal lead of the plurality of signal leads extend to a preset edge area of the base substrate;
covering a protection film on the first surface and the second surface of the base substrate, wherein the protection film covers an area outside the preset edge area; and
forming a plurality of through structures and a plurality of metal film connecting portions at the preset edge area and in one-to-one correspondence to the respective signal lines, wherein each through structure of the plurality of through structures connects the first surface and the second surface, each metal film connecting portion of the plurality of metal film connecting portions at least comprises a first metal film connecting portion plated on a side wall of a corresponding through structure, and two ends of the each metal film connecting portion are respectively connected to a corresponding signal line and a corresponding signal lead.

9. The method for preparing a micro LED display panel according to claim 8, wherein the each metal film connecting portion further comprises a second metal film connecting portion and a third metal film connecting portion, wherein the second metal film connecting portion is plated around the corresponding through structure on the first surface, the third metal film connecting portion is plated around the corresponding through structure on the second surface, the second metal film connecting portion is connected to the first metal film connecting portion and the corresponding signal line, and the third metal film connecting portion is connected to the first metal film connecting portion and the corresponding signal lead.

10. The method for preparing a micro LED display panel according to claim 8, wherein the forming the plurality of through structures and the plurality of metal film connecting portions at the preset edge area and in one-to-one correspondence to the respective signal lines, comprises:
forming a plurality of through holes at the preset edge area and in one-to-one correspondence to the respective signal lines, wherein centers of the plurality of through holes are located on a same cutting line;
at least plating metal films on side walls of respective through holes of the plurality of through holes;
cutting the base substrate along the cutting line, and forming the plurality of through structures on a cutting surface connecting the first surface and the second surface, wherein the plurality of through structures comprise concave parts that are parts of the side walls of the respective through holes; and
forming the plurality of metal film connecting portions.

11. The method for preparing a micro LED display panel according to claim 8, wherein the forming the plurality of through structures and the plurality of metal film connecting portions at the preset edge area and in one-to-one correspondence to the respective signal lines, comprises:
forming a plurality of through holes at the preset edge area and in one-to-one correspondence to the respective signal lines, wherein centers of the plurality of through holes are located on a same cutting line;
cutting the base substrate along the cutting line, and forming the plurality of through structures on a cutting surface connecting the first surface and the second surface, wherein the plurality of through structures comprise concave parts that are parts of the side walls of the respective through holes;
at least plating metal films on the cutting surface on which the plurality of through structures are located; and
grinding to remove the metal films arranged at an area outside the plurality of through structures, and forming the plurality of metal film connecting portions.

12. The method for preparing a micro LED display panel according to claim 8, wherein the forming the plurality of through structures and the plurality of metal film connecting portions at the preset edge area and in one-to-one correspondence to the respective signal lines, comprises:
forming a plurality of micro through holes at the preset edge area and in one-to-one correspondence to the respective signal lines;
at least plating metal films on a side wall of the plurality of micro through holes, and forming the plurality of metal film connecting portions; and
tearing off the protection film.

13. The method for preparing a micro LED display panel according to claim 8, wherein cross-sectional shape of the plurality of through structures parallel to the first surface is a circle or an arc, a diameter of the circle ranges from 10 μm to 50 μm, and a diameter of a circle where the arc is located ranges from 50 μm to 100 μm.

14. The method for preparing a micro LED display panel according to claim 10, wherein a method of forming the plurality of through holes comprises any one of a laser method, a sandblasting method or an etching method.

15. The method for preparing a micro LED display panel according to claim 10, wherein a method of plating the metal films comprises any one of a magnetron sputtering method, a three-dimensional evaporation method, a micro plating method or an electroless plating method.
